(19) United States
(12) Patent Application Publication
(10) Pub. No.: US 2010/0155779 A1
(43) Pub. Date: Jun. 24, 2010

(54) Field Effect Transistor

(76) Inventors: Yasuhiro Murase, Tokyo (JP); Kazuki Ota, Tokyo (JP); Yasuhiro Okamoto, Tokyo (JP); Kouji Matsunaga, Tokyo (JP); Hironobu Miyamoto, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 11/992,755

(22) PCT Filed: Sep. 28, 2006
(86) PCT No.: PCT/JP2006/319381

§ 371 Date: Mar. 28, 2008

(30) Foreign Application Priority Data
Sep. 30, 2005 (JP) 2005-288253

(51) Int. Cl. H01L 29/78

(52) U.S. Cl. 257/192; 257/E29.255

(57) ABSTRACT

In a field effect transistor, a Group III nitride semiconductor layer structure containing a hetero junction, a source electrode 101 and a drain electrode 103 formed apart from each other over the Group III nitride semiconductor layer structure, and a gate electrode 102 disposed between these electrodes, are provided. Over the surface of the Group III nitride semiconductor layer structure, a SiO₂ film 122 containing oxygen as a constitutive element is provided, in contact with both side faces of the gate electrode 102. Over the surface of the Group III nitride semiconductor layer structure, a SiN film 121 is provided so as to cover the region between the SiO₂ film 122 and the source electrode 101, and the region between the SiO₂ film 122 and the drain electrode 103. The SiN film 121 is composed of a material different from that composing the SiO₂ film 122, and contains nitrogen as a constitutive element.

### TECHNICAL FIELD

The present invention relates to a field effect transistor using Group III nitride semiconductors.

### BACKGROUND ART

Group III nitride semiconductors represented by GaN are characterized by larger band gaps, larger electric field causing dielectric breakdown, and larger saturated drift velocity of electrons as compared with those of GaAs-base semiconductors, and are therefore expected as materials capable of realizing electronic devices excellent in terms of operation at high temperatures, high-speed switching operation, large power operation, and so forth.

Because the Group III nitride semiconductors have piezoelectric property, adoption of a hetero junction structure can make use of high-concentration, two-dimensional carrier gas generated at the hetero junction portions by spontaneous polarization and piezo-electric polarization. Therefore, the Group III nitride semiconductors can operate based on a mechanism different from that of field effect transistors composed of GaAs-base semiconductors which operate by contribution of carriers produced by doping of impurities.

In this sort of Group III nitride semiconductor elements, negative charge is induced in the surficial portion of the semiconductor layer structure, as the carrier gas generates at the hetero junction portion. Because thus-produced negative charge largely affects various characteristics of transistor, it may be important to develop a technique of controlling the surficial negative charge. This point will be explained below.

It has been known that, in a stacked structure of Group III nitride semiconductor containing a hetero junction, large charge generates in the channel layer, and also negative charge generates in the surficial portion of a semiconductor layer such as AlGaN due to piezo-electric polarization or the like (Non-Patent Document 1).

Such negative charge directly acts on the drain current, and strongly affects performances of the element. More specifically, when a large negative charge is generated in the surficial portion, maximum drain current in the alternative current operation may degrade as compared with that in the direct current operation. This phenomenon will be referred to as current collapse, hereinafter. The current collapse is not observed in the GaAs-base hetero junction element generating only an extremely small polarized charge, but is a phenomenon specific to the Group III nitride semiconductor element.

Aiming at solving the problem, the current collapse has conventionally been reduced by forming a surface protective layer (Patent Document 1 and Patent Document 2). With a structure having no protective film provided thereto, a sufficient drain current cannot be obtained under application of high voltage due to the current collapse, and it is therefore difficult to enjoy advantages of using the Group III nitride semiconductor material.

It has been known also that effect of suppressing the current collapse differs depending on materials used as the protective film, and that SiN is a material having a large effect of suppressing the current collapse. An example of conventional transistor using a SiN film as the protective film will be explained below.

FIG. 5 is a sectional view showing a configuration of a conventional hetero-junction field effect transistor (referred to as HJFET, hereinafter). This sort of HJFET is reported, for example, in Non-Patent Document 2.

In the HJFET, a buffer layer 211 composed of AlN, a GaN channel layer 212 and an AlGaN electron supply layer 213 are stacked in this order over a substrate 209 composed of sapphire. Further thereon, a source electrode 201 and a drain electrode 203 are formed, wherein these electrodes are brought into ohmic contact with the AlGaN electron supply layer 213. In addition, a gate electrode 202 is formed between the source electrode 201 and the drain electrode 203, wherein the gate electrode 202 is brought into Schottky contact with the AlGaN electron supply layer 213. On the topmost layer, a SiN film 221 is formed as the surface protective film.

The HJFET shown in FIG. 5 is manufactured by the procedures as described below.

First, on the substrate 209 composed of sapphire, a semiconductor is grown typically by growth methods such as molecular beam epitaxy (MBE) or metal organic vapor phase epitaxy (MOVPE). In this way, a semiconductor layer structure having the buffer layer 211 (20 nm thick) composed of undoped AlN, the undoped GaN channel layer 212 (2 μm thick), and the AlGaN electron supply layer 213 (25 nm thick) composed of undoped AlGaN stacked in this order from the substrate side may be obtained.

Next, a part of the epitaxial layer structure is etched off until the GaN channel layer 212 is exposed, to thereby form a mesa for isolating elements (not shown). Next, a metal such as Ti/Al is deposited on the AlGaN electron supply layer 213 by vacuum evaporation through a photoresist, to thereby form the source electrode 201 and the drain electrode 203, and the electrodes are then annealed at 650° C. so as to establish ohmic contact. In addition, a gate metal such as Ni/Au is deposited on the AlGaN electron supply layer 213 by vacuum evaporation through a photoresist, to thereby form the gate electrode 202 brought into Schottky contact with the AlGaN electron supply layer 213.

Next, the SiN film 221 (50 nm thick) is formed typically by plasma CVD. A part of the SiN film 221 is then etched off to thereby form openings allowing the AlGaN electron supply layer 213 to expose therein. By these procedures, the HJFET shown in FIG. 5 may be obtained.

[Patent Document 1] Japanese Laid-Open Patent Publication No. 2004-200248

[Patent Document 2] Japanese Laid-Open Patent Publication No. 2004-214471

[Patent Document 3] Japanese Laid-Open Patent Publication No. H11-54527

[Non-Patent Document 1] U. K. Mishra, P. Parikh, and Yi-Feng Wu, “AlGaN/GaN HEMTs—An overview of device operation and applications.”, Proc. IEEE, vol. 90, No. 6, pp. 1022-1031, 2002

[Non-Patent Document 2] 2001 International Electron Devices Meeting Digest (IEDM01-381 to 384), Y. Ando

### DISCLOSURE OF THE INVENTION

Investigation by the present inventors into the HJFET shown in FIG. 5, however, revealed that use of the SiN film as the protective film was excellent in terms of reducing the current collapse, but increased leakage current from the gate as compared with the case where the protective film was not formed. Accordingly, for the case where the SiN film was used as the protective film, large leakage current possibly flows during high voltage operation may be causative of breakdown of the gate electrode, and thereby inhibit stable operation of the element. Moreover, the leakage current from the gate sometimes resulted in degradation of RF (radio frequency) efficiency of the element, and thereby made it difficult to ensure characteristics necessary for transistors.

As described in the above, the Group III nitride semiconductor elements obtained by the conventional method of manufacturing were sometimes difficult to achieve characteristics necessary for transistors. As for the Group III nitride semiconductors, it is therefore necessary to develop elements having both properties of lowered current collapse and lowered current leakage from the gate.

The HJFET shown in FIG. 5 had a still more room for improvement also in parasitic capacitance between the gate electrode and the semiconductor layer.

The present invention is conceived after considering the above-described situations, and is to provide a technique of lowering current collapse and current leakage from the gate in the Group III nitride semiconductor field effect transistors, and lowering also parasitic capacitance in the vicinity of the gate electrode.

### MEANS FOR SOLVING THE PROBLEMS

In general, when negative voltage is applied to the gate of a transistor, electrons are injected into the semiconductor layer and the semiconductor layer is depleted from the surface thereof. If any surface of interfacial levels exists there, the electrons injected from the gate may be trapped by the surface or interfacial levels. As a consequence, breakdown of the gate may become less likely to occur even if applied with high voltage, and thereby higher gate resistive voltage may be obtained. However, there may be an increasing tendency of current collapse during the alternative-current operation, due to time constant of trapping and release of the electrons. On the other hand, when there is only a small amount of negative charge in the surficial portion, current collapse may be reduced, but voltage resistance under high voltage may be degraded due to scarceness of trappable electrons. Operation of the transistor is governed by such tradeoff relation. The depletion layer produced by the electrons injected into the semiconductor layer extends towards the drain electrode side of the gate electrode, so that electron field intensity becomes maximum on the drain electrode side of the gate electrode.

The current collapse occurs due to trapping of the moving electrons by surface or interfacial levels in semiconductor. The current collapse is therefore affected by the state of surface or boundary of semiconductor ranging from the gate electrode to the drain electrode.

The present inventors made investigations from this point of view, and found out that, in the field effect transistors using Group III nitride semiconductor, those less causative of current collapse, reduced in leakage current from the gate, and lowered in parasitic capacitance between the gate electrode and the semiconductor layer, may be realized by providing different insulating films in the region over the semiconductor layer in contact with the side faces of the gate electrode, and in the other regions. The present invention was completed based on such novel finding.

According to the present invention, there is provided a field effect transistor which includes:

a Group III nitride semiconductor layer structure containing a hetero junction;

a source electrode and a drain electrode formed, as being apart from each other, over the Group III nitride semiconductor layer structure;

a gate electrode disposed between the source electrode and the drain electrode;

a first insulating film provided over the surface of the Group III nitride semiconductor layer structure, in contact with both side faces of the gate electrode, and containing oxygen as a constitutive element; and

a second insulating film provided over the surface of the Group III nitride semiconductor layer structure, so as to cover the region between the first insulating film and the source electrode, and the region between the first insulating film and the drain electrode, composed of a material different from that composing the first insulating film, and containing nitrogen as a constitutive element.

In the present invention, different insulating films are provided over the Group III nitride semiconductor layer structure, in the region in contact with the side faces of the gate electrode, and in the other regions. Accordingly, the region determining voltage resistant characteristics of the gate and the region causative of current collapse can now be dealt with separate measures, and thereby desirable performances characterized by less current collapse and less leakage current from the gate may be realized in a stable manner.

The first insulating film provided in the vicinity of the gate electrode used herein may be an insulating film capable of forming a large level density at the interface with the Group III nitride semiconductor layer structure, in view of raising the voltage resistant characteristics. In this way, concentration of electric field at the drain electrode side of the gate electrode may be moderated, and thereby the leakage current from the gate may be reduced.

On the other hand, the second insulating film having a low interfacial level density is used in the regions other than that in the vicinity of the gate electrode. In this way, the current collapse possibly occurs between the gate electrode and the drain electrode may be suppressed.

More specifically, an oxygen-containing insulating film is formed as the first insulating film in the vicinity of the gate electrode, and a nitrogen-containing second insulating film is formed in the regions other than those in the vicinity of the gate electrode. Preferably, the insulating film in the vicinity of the gate electrode is formed using a SiO₂ film, and a SiN film is formed in the regions other than those in the vicinity of the gate electrode. In this way, a transistor reduced in current collapse, reduced in leakage current from the gate, and made more suitable for raising output may be obtained.

The first insulating film in the present invention is provided on both side faces of the gate electrode, so that leakage current from the gate may exactly be suppressed, and thereby parasitic capacitance between the side faces of the gate electrode and the Group III nitride semiconductor layer structure may be reduced. It is to be understood now that “be provided on both side faces of the gate electrode” means that the first insulating film is provided on both sides of the gate electrode, in a sectional view taken along the gate length.

Each of the regions covered by the first insulating film may be defined as a region which extends up to 40 nm or more, and preferably 300 nm or more, from the edge portion on the drain electrode side of the gate electrode, wherein the upper limit may be defined by 30% of the distance between the gate electrode and the drain electrode. Thickness of the first insulating film in the vicinity of the gate electrode may be defined typically as 5 nm and more, and preferably 20 nm or more. In this way, characteristics satisfying both of suppression of current collapse and voltage resistance of the gate in the tradeoff relation may be obtained.

Also any arbitrary combinations of these configurations, and any exchanges of expressions of the present invention among method, apparatus and so forth may be effective as embodiments of the present invention.

For example, in the present invention, the first insulating film formed at around the gate electrode may cover the entire surface of the gate electrode. In this way, the gate electrode may be protected, and the life time and reliability may distinctively be improved.

In the present invention, in the region between the gate electrode and the drain electrode, an electric field control electrode or a field plate portion may be provided while placing the first and second insulating films over the Group III nitride semiconductor layer structure in between. In this way, the balance between current collapse and voltage resistance of the gate may drastically be improved.

In the present invention, the electric field control electrode or the field plate portion may be configured as being controllable independently from the gate electrode. In other words, the electric field control electrode and the gate electrode may be applied with different levels of potential. By virtue of this configuration, the field effect transistor may be operated at optimum conditions.

In the present invention, the gate electrode may have a T-form or Y-form. In this way, resistivity of the gate may be reduced, high frequency characteristics may drastically be improved by virtue of enhanced gain, and in particular for a thin gate structure having a gate length of 0.25 μm or smaller, high-voltage and high-gain operation may be realized.

The Group III nitride semiconductor layer structure may be configured typically as containing a channel layer composed of InₓGa₁₋ₓN (0≦x≦1) and an electron supply layer composed of Al_{y}Ga_{1-y}N (0≦y≦1). The order of stacking the channel layer and the electron supply layer may be arbitrary.

In the present invention, another possible configuration is such that a field contact layer is provided between the source electrode and the surface of the Group III nitride semiconductor layer structure, and between the drain electrode and the surface of the Group III nitride semiconductor layer structure. The configuration having the contact layer is referred to as wide-recess structure. When this configuration is adopted, electric field concentration at the edge portion on the drain side of the gate electrode may be dispersed and moderated, in a more effective manner. The recessed structure adopted herein may also be a multi-stepped recess.

In the present invention, the distance between the gate electrode and the drain electrode may be set longer than the distance between the gate electrode and the source electrode. This configuration is so-called offset structure, and can more effectively disperse and moderate concentration of electric field at the edge portion on the drain side of the gate electrode.

### EFFECT OF THE INVENTION

As has been explained in the above, according to the present invention, a field effect transistor reduced in current collapse and leakage current from the gate, and also reduced in parasitic capacitance in the vicinity of the gate electrode may be realized.

### BRIEF DESCRIPTION OF THE DRAWINGS

The above and other objects, advantages and features of the present invention will be more apparent from the following preferable embodiments described in conjunction with the accompanying drawings.

FIG. 1 is a sectional view showing a configuration of a field effect transistor according to the embodiment;

FIG. 2 is a sectional view showing a configuration of a field effect transistor according to the Example;

FIG. 3 is a sectional view showing a configuration of a field effect transistor according to the Example;

FIG. 4 is a sectional view showing a configuration of a field effect transistor according to the Example;

FIG. 5 is a sectional view showing a configuration of a conventional field effect transistor;

FIG. 6 is a sectional view showing steps of manufacturing the field effect transistor shown in FIG. 1;

FIG. 7 is a sectional view showing steps of manufacturing the field effect transistor shown in FIG. 1;

FIG. 8 is a sectional view showing steps of manufacturing the field effect transistor shown in FIG. 1;

FIG. 9 is a sectional view showing steps of manufacturing the field effect transistor shown in FIG. 1;

FIG. 10 is a drawing showing two-terminal voltage resistance characteristics of an HJFET of the Example and a conventional HJFET;

FIG. 11 is a drawing showing relations between magnitude of current collapse and gate leakage current at a drain voltage of 10 V of an HJFET of the Example and a conventional HJFET;

FIG. 12 is a sectional view showing steps of manufacturing the field effect transistor shown in FIG. 3;

FIG. 13 is a sectional view showing steps of manufacturing the field effect transistor shown in FIG. 3;

FIG. 14 is a sectional view showing steps of manufacturing the field effect transistor shown in FIG. 3;

FIG. 15 is a sectional view showing steps of manufacturing the field effect transistor shown in FIG. 3;

FIG. 16 is a sectional view showing a configuration of a field effect transistor according to the Example;

FIG. 17 is a sectional view showing a configuration of a field effect transistor according to the Example;

FIG. 18 is a sectional view showing a step of manufacturing the field effect transistor shown in FIG. 2;

FIG. 19 is a sectional view showing a step of manufacturing the field effect transistor shown in FIG. 2;

FIG. 20 is a sectional view showing a step of manufacturing the field effect transistor shown in FIG. 2; and

FIG. 21 is a sectional view showing a configuration of a field effect transistor according to Example.

### BEST MODE FOR CARRYING OUT THE INVENTION

Embodiments of the present invention will be explained below, in conjunction with the attached drawings, referring to HJFETs having, as the Group III nitride semiconductor, an AlGaN electron supply layer/GaN channel layer and a surface protective film (simply referred to as “protective film”, hereinafter). In all drawings, any common constituents will be given with same reference numerals, and explanations therefor will not be repeated. In this specification, any stacked layer structure will be expressed as “upper layer/lower layer (substrate side)”.

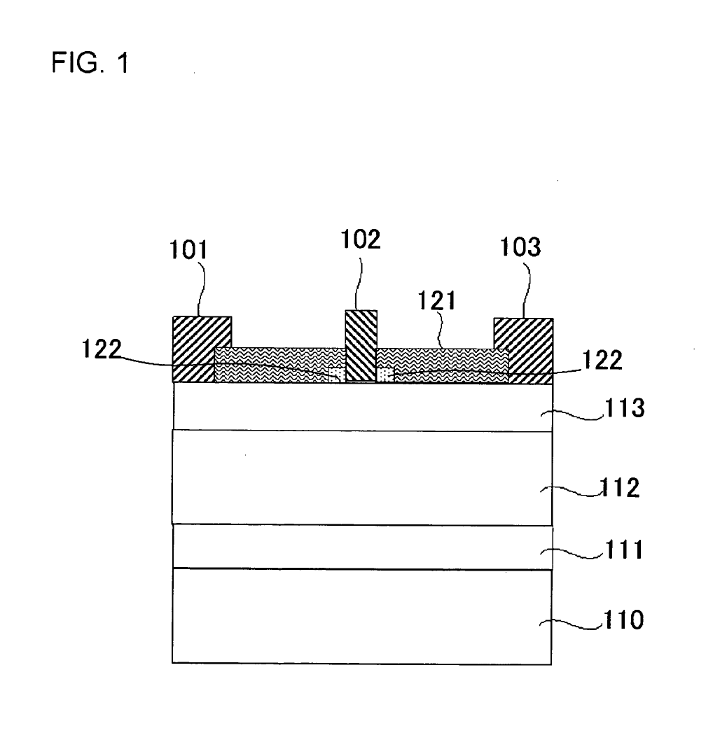

FIG. 1 is a drawing showing a basic configuration of a field effect transistor of this embodiment.

The field effect transistor (HJFET) shown in FIG. 1 has a Group III nitride semiconductor layer structure containing a hetero junction (GaN channel layer 112, AlGaN electron supply layer 113), a source electrode 101 and a drain electrode 103 formed, as being apart from each other, over the Group III nitride semiconductor layer structure, and a gate electrode 102 disposed between the source electrode 101 and the drain electrode 103. Because the HJFET has a hetero junction structure, high-concentration, two-dimensional carrier gas generated at the hetero junction portions by spontaneous polarization and piezo-electric polarization may be used.

The HJFET also has a first insulating film (SiO₂ film 122) and a second insulating film (SiN film 121).

The SiO₂ film 122 is provided over the surface of the AlGaN electron supply layer 113, at around the side faces of the gate electrode 102. The SiO₂ film 122 is a film containing oxygen as a constitutive element, provided in contact with both side faces of the gate electrode 102, and covers a region at around the bottom end of the gate electrode 102.

The surface of the AlGaN electron supply layer 113 herein may be the surface or therearound of the AlGaN electron supply layer 113, and for example the AlGaN electron supply layer 113 may directly contact with the SiN film 121 and the SiO₂ film 122. Alternatively, any interstitial layer may be provided between the AlGaN electron supply layer 113, and the SiN film 121 and SiO₂ film 122, so far as the configuration expresses an effect of suppressing current collapse and leakage current from the gate.

The SiO₂ film 122 is provided in contact with both side faces of the gate electrode 102. In other words, the SiO₂ film 122 is provided on both sides of the gate electrode 102 in a sectional view taken along the gate length. Therefore, the HJFET shown in FIG. 1 is configured as being excellent in readiness of manufacturing. In addition, concentration of electric field at the edge portion of the gate may effectively be suppressed, and parasitic capacitance between both side faces of the gate electrode 102 and the AlGaN electron supply layer 113 may effectively be reduced.

The SiO₂ film 122 is provided at around the gate electrode 102. Provision at around the gate electrode 102 means that the SiO₂ film 122 is provided in a region only to as large as allowing the SiN film 121 to exhibit the effect of suppressing current collapse, even if the SiO₂ film 122 is provided therein. In view of reliably suppress the current collapse, the region of the surface of the AlGaN electron supply layer 113 to be covered with the SiO₂ film 122 is preferably such as extending up to 500 nm or less, preferably 400 nm or less, from the edge portion on the drain electrode side of the gate electrode 102. In this region, the AlGaN electron supply layer 113 is brought into contact with the SiO₂ film 122, and in other regions, the AlGaN electron supply layer 113 is brought into contact with the SiN film 121.

In view of reliably suppressing leakage current from the gate, the region of the surface of the AlGaN electron supply layer 113 to be covered with the SiO₂ film 122 is preferably such as extending up to 40 nm or more, preferably 300 nm or more, from the edge portion on the drain electrode side of the gate electrode 102.

The SiO₂ film 122 is provided at around the bottom end of the gate electrode 102. The region at around the bottom end of the gate electrode 102 may range to as large as allowing sufficient suppression of leakage voltage from the gate, and may be brought into contact with the bottom end of the gate electrode 102, or may be apart from the bottom end of the gate electrode 102, so far as such effect may be expressed.

The SiO₂ film 122 is provided selectively at around the side faces of the gate electrode 102. Provision at around the side faces of the gate electrode 102 herein means that the SiO₂ film 122 is provided in a region only to as large as allowing the SiN film 121 to exhibit the effect of suppressing current collapse in the region between the gate electrode 102 and the source electrode 101 or the drain electrode 103, even if the SiO₂ film 122 is provided therein.

Thickness of the SiO₂ film 122 in the direction of stacking is typically adjusted to 5 nm or larger, and preferably 20 nm or larger, in view of reliably suppressing leakage current from the gate. On the other hand, thickness of the SiO₂ film 122 in the direction of stacking is typically adjusted to 200 nm or smaller, and preferably 100 nm or smaller. In this way, the current collapse may more effectively be suppressed.

As shown in FIG. 1, the SiO₂ film 122 has no step portion. Thickness of the SiO₂ film 122 is typically smaller than that of the SiN film 121. By this configuration, the SiO₂ film 122 may selectively be provided in a minimum necessary region, and may thereby allow the SiN film 121 to express an effect of reducing current collapse in a more distinctive manner.

The SiN film 121 functions, on the surface of the AlGaN electron supply layer 113, as a surface protective film capable of suppressing current collapse, and covers the region between the SiO₂ film 122 and the source electrode 101, and the region between the SiO₂ film 122 and the drain electrode 103. The SiN film 121 is composed of a material different from that of the SiO₂ film 122. Alternatively, in place of the SiN film 121, also other films containing nitrogen as a constitutive element, such as SiON film, SiCN film and the like, may be adoptable.

The SiN film 121 is provided so as to cover the top surface of the SiO₂ film 122, while being brought into contact with the side faces of the SiO₂ film 122, the side faces of the gate electrode 102, the side face of the source electrode 101, and side face of the drain electrode 103. At the side faces of the gate electrode 102, the SiO₂ film 122 and the SiN film 121 are stacked upwardly from the bottom.

The HJFET shown in FIG. 1 has an overlapped region where the SiN film 121 is stacked on the SiO₂ film 122. Therefore, the insulating film which functions as a surface protective film over the AlGaN electron supply layer 113 is configured as being lowered in mean value of dielectric constant in the overlapped region. In addition, the insulating film, which functions as a surface protective film, is configured so as to stepwisely change therein mean value of dielectric constant from the gate electrode 102 towards the drain electrode 103, so that concentration of electric field at the edge portion on the drain electrode side of the gate electrode 102 may be suppressed in a more effective manner.

In FIG. 1, when viewed in the thickness-wise direction of the gate electrode 102, the SiO₂ film 122 is provided selectively at around the bottom end of the gate electrode 102, and the SiN film 121, which functions as a surface protective film, is provided over the SiO₂ film 122. In other words, the SiN film 121 is provided over the entire region between the gate electrode 102 and the drain electrode 103, and the entire region between the gate electrode 102 and the source electrode 101. On the side faces of the gate electrode 102, a part of the SiN film 121 is deficient, and the SiO₂ film 122 is filled in the deficient portion. By this configuration, current collapse may be reduced in a more effective manner.

Thickness of the SiN film 121 in the thickness-wise direction of the substrate 110, is preferably adjusted, for example, to 5 nm or larger, and more preferably 20 nm or larger, from the viewpoint of suppressing current collapse at the interface in a further reliable manner. In view of suppressing current collapse and improving the voltage resistance of the gate, so as to more effectively solve the tradeoff problem therebetween, the thickness of the SiN film 121 is preferably adjusted, for example, to 300 nm or smaller, and more preferably to 100 nm or smaller.

The Group III nitride semiconductor layer structure contains the channel layer (GaN channel layer 112) composed of InₓGa₁₋ₓN (0≦x≦1), and an electron supply layer (AlGaN electron supply layer 113) composed of Al_{y}Ga_{1-y}N (0≦y≦1), and the hetero-interface is an interface between InₓGa₁₋ₓN and Al_{y}Ga_{1-y}N. It is now necessary to avoid that both of x and y have a value of zero at the same time in the formulae.

In this embodiment, by using the SiO₂ film 122 as a surface protective film effectively suppressing leakage current from the gate, and by providing it selectively at around the bottom end of the gate electrode, and further by providing the SiN film 121 as a surface protective film effectively suppressing current collapse, both of improvement in voltage resistance by virtue of reduced leakage voltage from the gate and suppression of current collapse may be realized at the same time.

Patent Document 1 and Patent Document 2 mentioned above in BACKGROUND ART describe configurations having the SiO₂ film provided in contact with the side face of the gate electrode, only in the region between the gate electrode and the drain electrode.

In contrast, this embodiment adopts a configuration having the SiO₂ film 122 provided on both sides of the gate electrode 102 in a sectional view, and thereby, in addition to an effect of suppressing current collapse and leakage current from the gate, parasitic capacitance between the side faces of the gate electrode 102 and the AlGaN electron supply layer 113 both on the source electrode 101 side and the drain electrode 103 side may be reduced.

Although in a different technical field, Patent Document 3 describes provision of a high resistivity layer composed of undoped GaAs, over a layered structure of GaAs-base semiconductor field effect transistor. In Patent Document 3, decrease in source-drain current is suppressed by covering the surface of the high resistivity layer composed of undoped GaAs with an insulating film.

In contrast in this embodiment, unlikely to the literature, a problem of tradeoff between leakage current from the gate and current collapse in HJFET, raising a subject matter of current collapse, may be solved by covering the entire exposed surface of the AlGaN electron supply layer 113 with two species of insulating films represented by the SiN film 121 and the SiO₂ film 122, and by disposing the insulating films respectively in their appropriate regions.

Embodiments of the present invention will further be explained below, referring to the Examples. The Examples below will explain cases where a c-plane SiC was used as a substrate on which the Group III nitride semiconductor layer is grown.

### EXAMPLES

### First Example

This Example relates to the HJFET shown in FIG. 1. The HJFET is formed over the substrate 110 composed of SiC or the like.

Over the substrate 110, a buffer layer 111 composed of a semiconductor layer is formed. Over the buffer layer 111, a GaN channel layer 112 is formed. Over the GaN channel layer 112, the AlGaN electron supply layer 113 is formed.

Over the AlGaN electron supply layer 113, the source electrode 101 and the drain electrode 103 are provided as being brought into ohmic contact therewith. Over the AlGaN electron supply layer 113, the gate electrode 102 is provided as being brought into Schottky contact.

Over the surface of the AlGaN electron supply layer 113, the SiO₂ film 122 is provided at around the gate electrode 102, and the SiN film 121 is formed so as to cover the surface of the AlGaN electron supply layer 113 and the SiO₂ film 122, as being extended from the gate electrode 102 towards the source electrode 101 and the drain electrode 103.

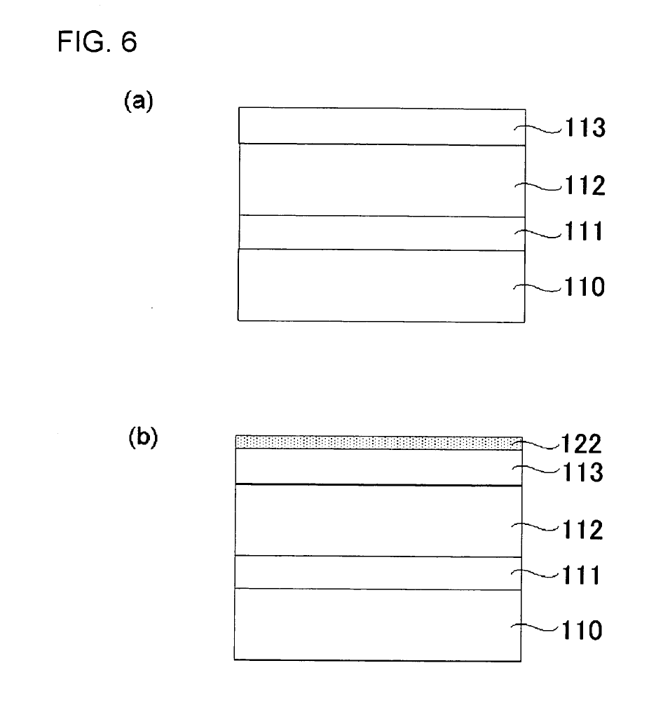

FIG. 6 to FIG. 9 are sectional views showing process steps of manufacturing the HJFET shown in FIG. 1. A method of manufacturing the HJFET shown in FIG. 1 will be explained below, referring to these drawings.

First, over the substrate 110 composed of SiC, a semiconductor is grown typically by molecular beam epitaxy (MBE), metal organic vapor phase epitaxy (MOVPE) or the like. In this way, a semiconductor layer structure having, as viewed from the substrate 110 side, the buffer layer 111 (20 nm thick) composed of undoped AlN, the undoped GaN channel layer 112 (2 μm thick), and the AlGaN electron supply layer 113 (25 nm thick) composed of undoped AlGaN stacked therein in this order (FIG. 6(a)) is obtained.

Next, over the AlGaN electron supply layer 113, the SiO₂ film 122 (20 nm thick) is formed typically by normal-pressure CVD (FIG. 6(b)).

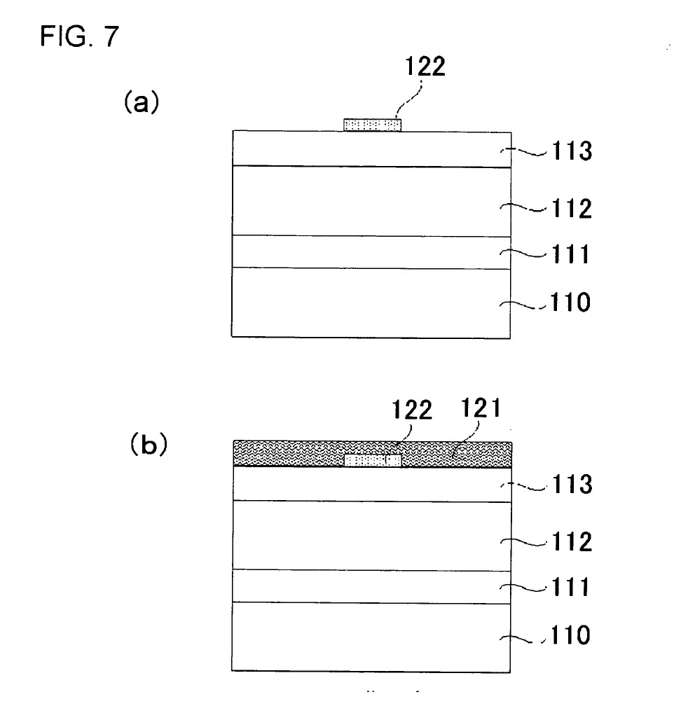

Next, a predetermined region of the SiO₂ film 122 and a predetermined region of the epitaxial layer structure are selectively etched off until the GaN channel layer 112 exposes, to thereby form a mesa (not shown) for element isolation. A predetermined region of the SiO₂ film 122 is then selectively removed so as to obtain a predetermined geometry, to thereby allow the AlGaN electron supply layer 113 to expose (FIG. 7(a)).

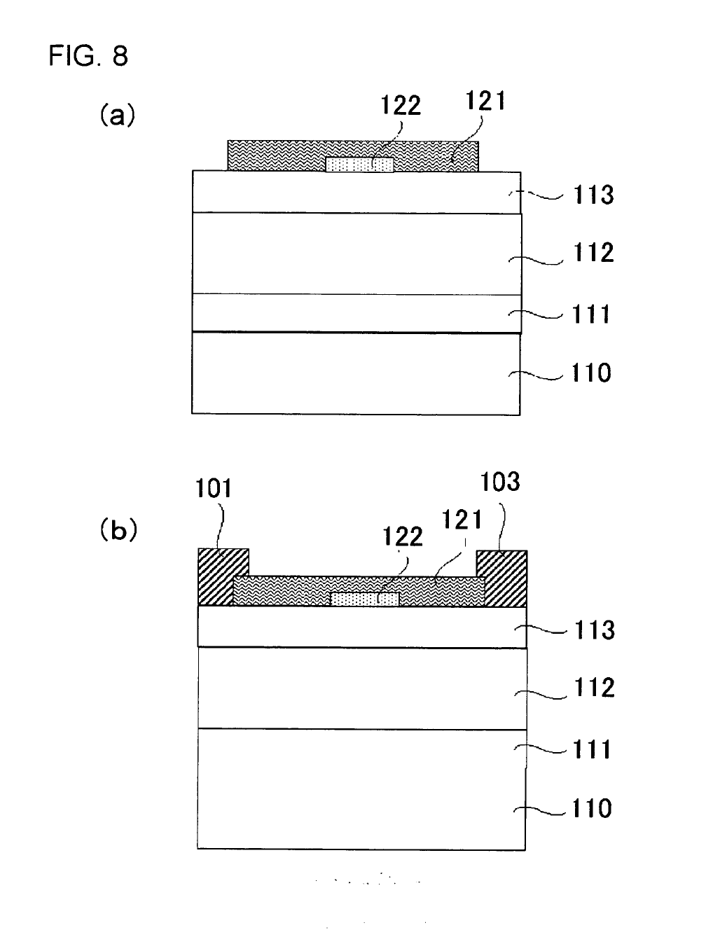

Next, the SiN film 121 (60 nm) is formed typically by plasma CVD, over the AlGaN electron supply layer 113 and the SiO₂ film 122 (FIG. 7(b)). A predetermined region of the SiN film 121 is then etched through a resist such as photoresist, used as a mask, until the AlGaN electron supply layer 113 exposes (FIG. 8(a)). The SiN film 121 herein is designed so as to cover the entire surface of the SiO₂ film 122. Thereafter, a metal such as Ti/Al is deposited over the AlGaN electron supply layer 113, to thereby form the source electrode 101 and the drain electrode 103 as being partially overlapped with the SiN film 121, and the product was annealed at 650° C. so as to establish ohmic contact (FIG. 8(b)).

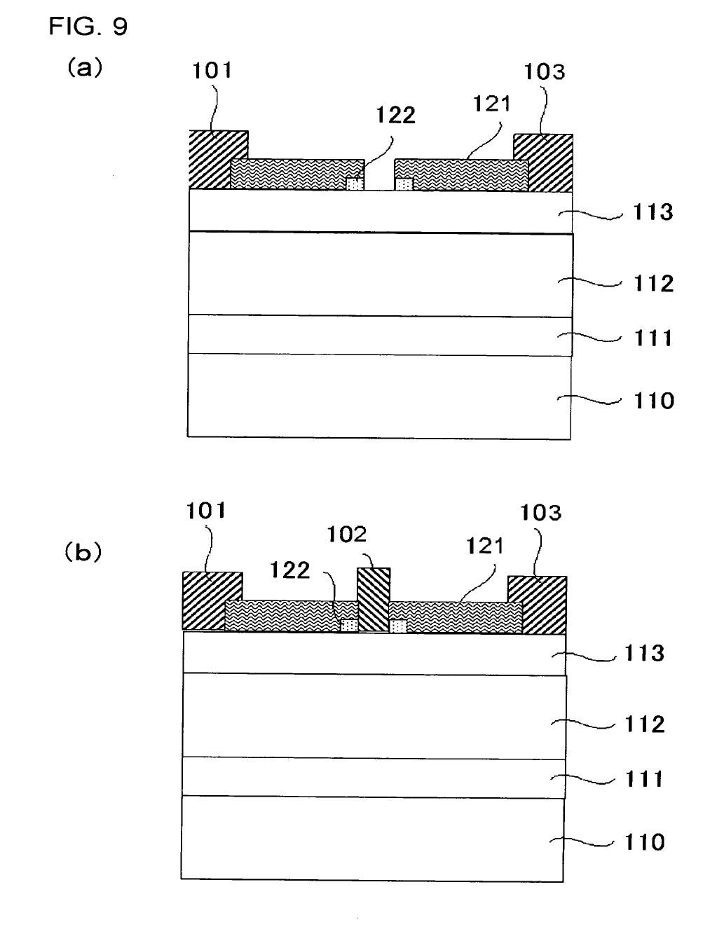

A predetermined region of the SiN film 121 and the SiO₂ film 122 was then selectively etched off through a resist film such as photoresist, used as a mask, to thereby form a recess extending through the SiN film 121 and SiO₂ film 122 (FIG. 9(a)). In this process, the recess is formed so as to leave the SiO₂ film 122 laterally on the source side and drain side thereof, so as to allow the SiN film 121 and the SiO₂ film 122 to expose to the side faces thereof. The recess also allows the AlGaN electron supply layer 113 to expose to the bottom thereof.

Over the AlGaN electron supply layer 113 exposed at the bottom of the opening, a metal such as Ni/Au, destined for a gate metal, is deposited so as to form the gate electrode 102 brought into Schottky contact with the AlGaN electron supply layer 113 (FIG. 9(b)). By these procedures, the HJFET shown in FIG. 1 may be obtained.

Although this Example was explained referring to the case where the gate electrode 102 has a rectangular section, the sectional geometry of the gate electrode 102 in this Example and other Examples of this specification is not limited to rectangle, allowing the gate electrode 102 to be widened upward such as having a T-shape structure or a Y-shape structure. In this way, high-frequency characteristics of the HJFET may further be improved. Such gate electrode 102 may be formed typically by electron beam lithography.

For the case where the T-shape structure or the Y-shape structure is adopted, the SiO₂ film 122 may be provided in a region recessed inwardly (towards the gate) from the edge on the drain side of the upper widened portion of the gate electrode 102, in a sectional view taken along the direction of gate length. In this way, leakage current from the gate and current collapse may further effectively be suppressed.

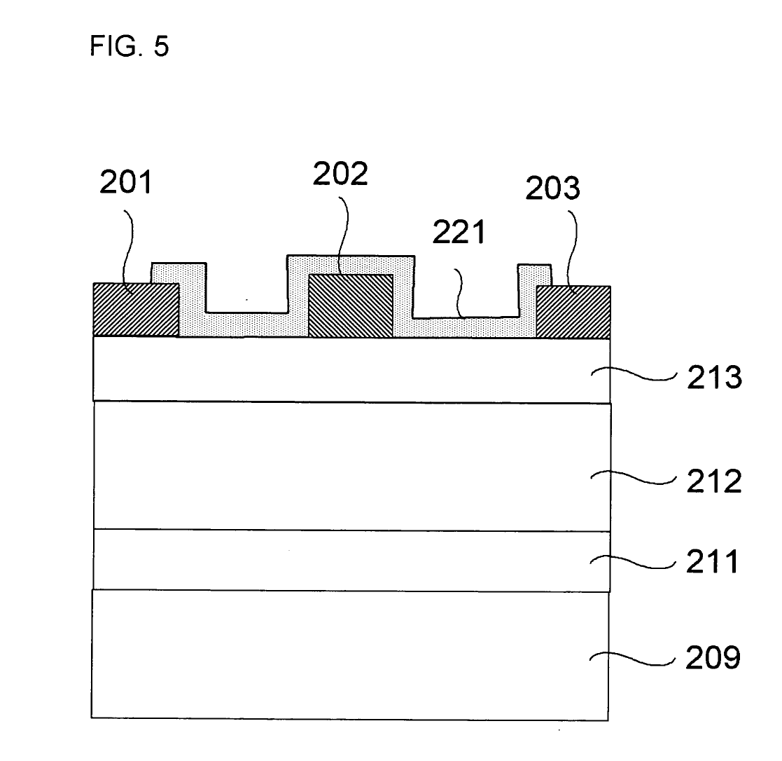

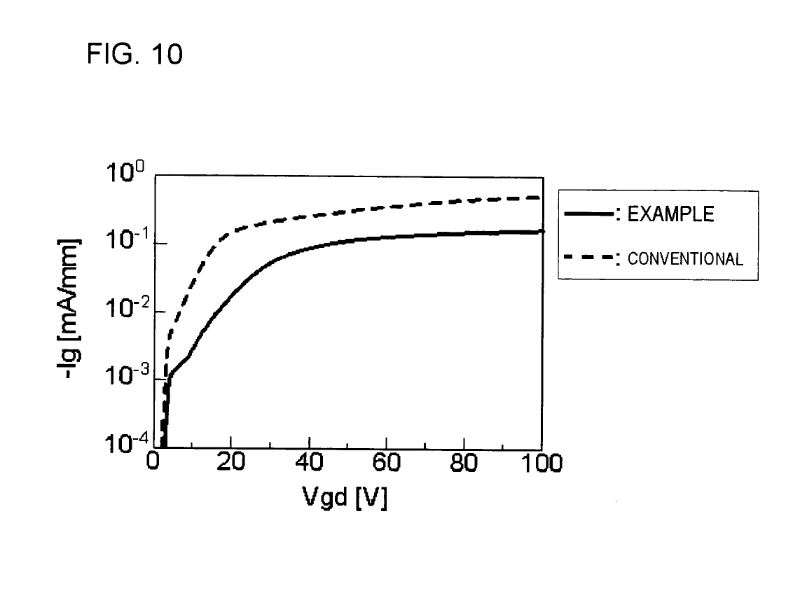

FIG. 10 shows two-terminal voltage resistance characteristics of the HJFET of the Example (FIG. 1) and the HJFET having the conventional structure (FIG. 5). It is obvious from FIG. 10 that, this Example is less in leakage current from the gate (ordinate) as compared with the conventional structure, indicating improved voltage resistance characteristics. Because the SiO₂ film 122 in this Example is selectively disposed at around the side faces of the gate electrode 102, the SiO₂ film 122 may moderate concentration of electric field in the gate electrode 102 on the drain electrode side thereof during high-voltage operation. An element improved in the voltage resistance of the gate thereof may be obtained.

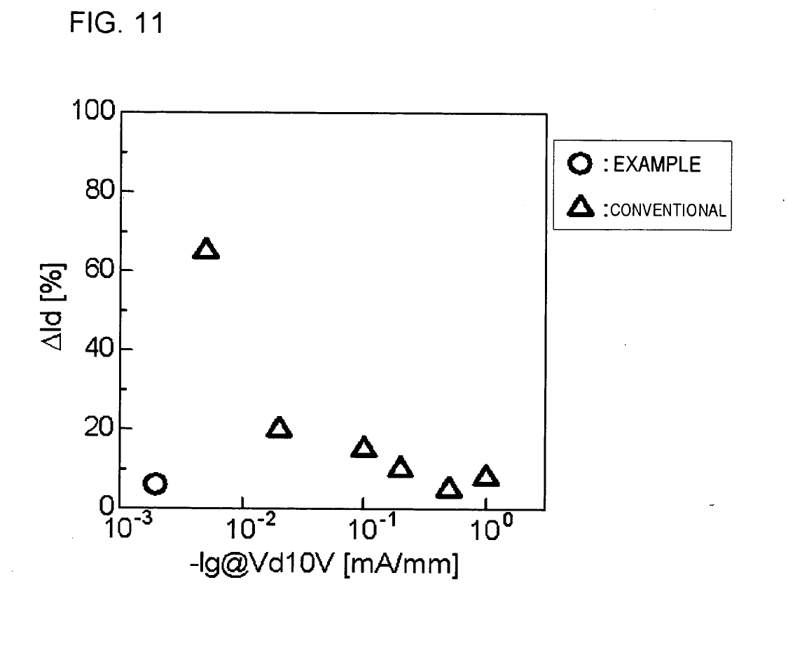

FIG. 11 is a drawing showing relations between amount of current collapse and gate leakage current at a drain voltage of 10 V of the HJFET of Example (FIG. 1) and the HJFET having the conventional structure (FIG. 5). It is understood that the conventional HJFET suffers from a tradeoff relation, showing smaller current collapse under larger leakage current from the gate, and conversely showing larger current collapse under smaller leakage current from the gate. In contrast, it is understood that the HJFET of this Example successfully got rid of the tradeoff relation of the conventional structure, showing drastic improvement in two subjects, that are lowering in current collapse and lowering in leakage current from the gate.

As has been described in the above, an HJFET reduced in current collapse, reduced in leakage current from the gate, and capable of stably ensuring large output may be obtained. The HJFET of this Example is also operable under high voltage. In the HJFET of the Example, parasitic capacitance between the side faces of the gate electrode 102 and the AlGaN electron supply layer 113 may effectively be reduced.

Examples explained below will emphasize aspects different from those in the First Example.

### Second Example

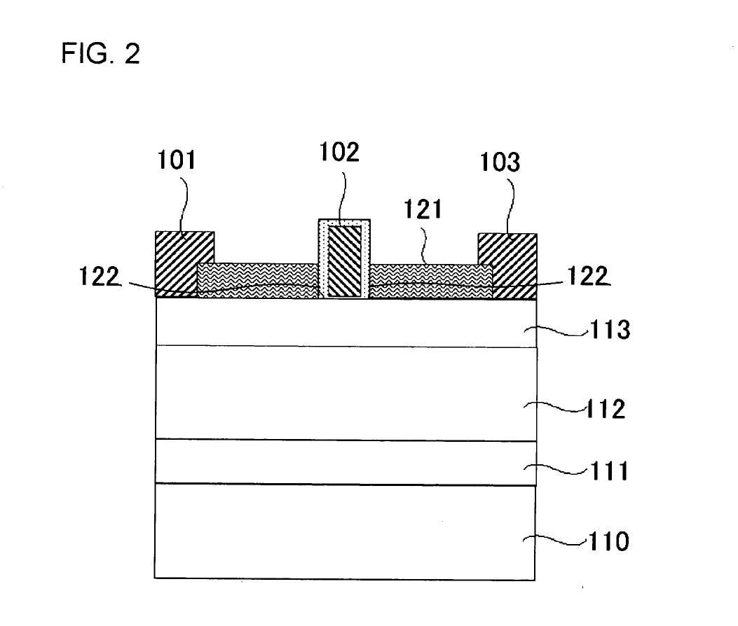

FIG. 2 is a sectional view showing a configuration of a HJFET of this Example.

In this HJFET, the SiO₂ film 122 covers the entire top surface of the gate electrode 102 in a sectional view taken along the direction of gate length. The SiO₂ film 122 and the SiN film 121 do not overlap with each other.

The HJFET is formed over the substrate 110 typically composed of SiC.

Over the substrate 110, the buffer layer 111 composed of semiconductor layer is formed. Over the buffer layer 111, the GaN channel layer 112 is formed. Over the GaN channel layer 112, the AlGaN electron supply layer 113 is formed. Over the AlGaN electron supply layer 113, the source electrode 101 and the drain electrode 103 are formed as being brought into ohmic contact therewith. In the region between the source electrode 101 and the drain electrode 103, the gate electrode 102 is provided over the surface of the AlGaN electron supply layer 113, as being brought into Schottky contact therewith.

Over the surface of the AlGaN electron supply layer 113, the SiO₂ film 122 is formed at around the gate electrode 102, so as to cover the side faces of the gate electrode 102. The SiO₂ film 122 herein covers the entire ranges of the side faces and the top surface of the gate electrode 102. The SiN film 121 is provided in the region between the SiO₂ film 122 and the source electrode 101, and in the region between the SiO₂ film 122 and the drain electrode 103.

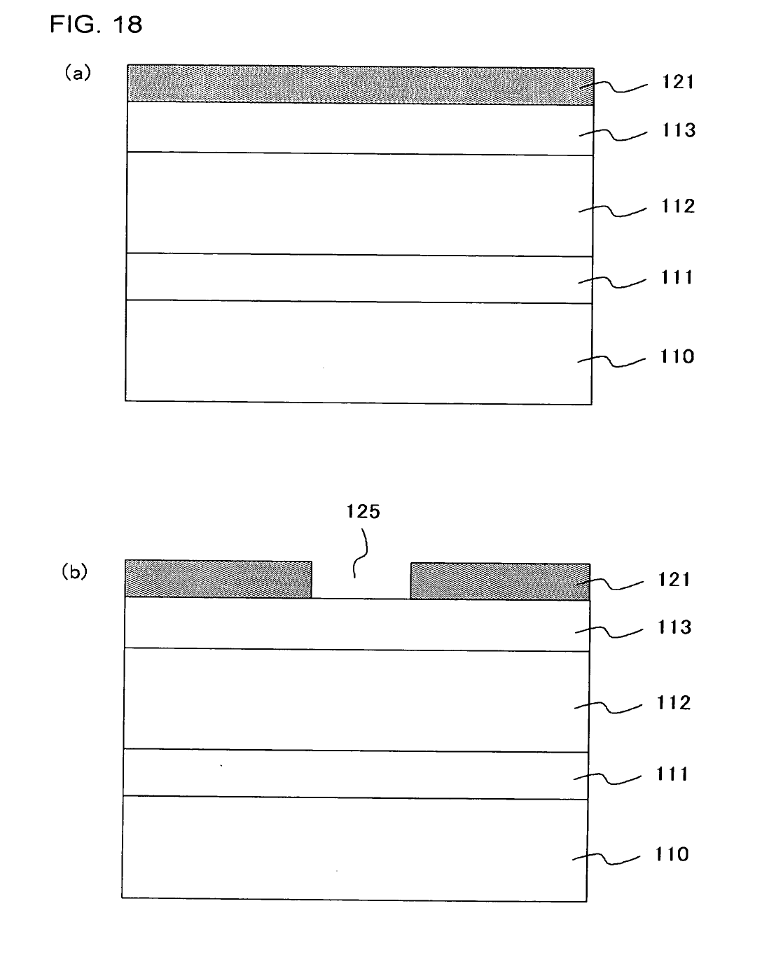

FIG. 18 to FIG. 20 are sectional views showing process steps of manufacturing the HJFET shown in FIG. 2. Paragraphs below will explain a method of manufacturing the HJFT shown in FIG. 2, referring to these drawings.

First, over the substrate 110 composed of SiC, a semiconductor is grown typically by molecular beam epitaxy (MBE), metal organic vapor phase epitaxy (MOVPE) or the like. In this way, a semiconductor layer structure having, as viewed from the substrate 110 side, the buffer layer 111 (20 nm thick) composed of undoped AlN, the undoped GaN channel layer 112 (2 μm thick), and the AlGaN electron supply layer 113 (25 nm thick) composed of undoped AlGaN stacked therein in this order (FIG. 6(a)) is obtained.

Next, over the AlGaN electron supply layer 113, the SiN film 121 (60 nm thick) is formed typically by plasma CVD process (FIG. 18(a)).

Next, a predetermined region of the SiN film 121 and a predetermined region of the epitaxial layer structure are selectively etched off until the GaN channel layer 112 exposes, to thereby form a mesa (not shown) for element isolation. A predetermined region of the SiN film 121 is then selectively removed so as to obtain a predetermined geometry, to thereby form a recess 125. The AlGaN electron supply layer 113 exposes to the bottom of the recess 125 (FIG. 18(b)).

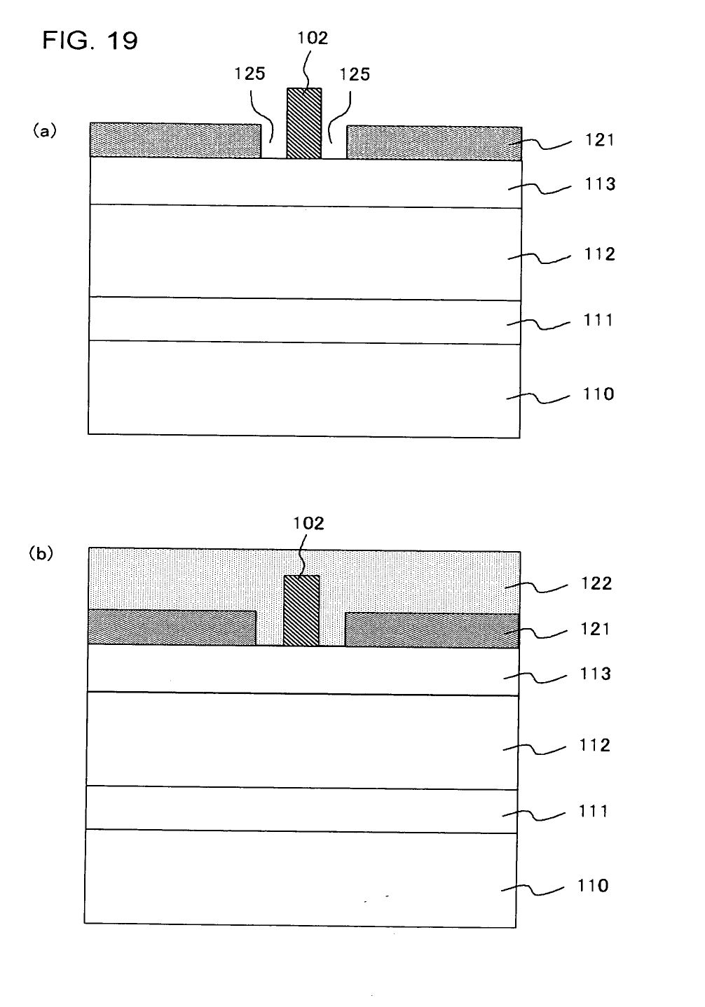

Next, over the AlGaN electron supply layer 113 exposed at the bottom of the recess 125, a metal such as Ni/Au, destined for a gate metal, is deposited so as to form the gate electrode 102 brought into Schottky contact with the AlGaN electron supply layer 113 in a predetermined region in the recess 125, while leaving exposed portions of the AlGaN electron supply layer 113 on both sides of the gate electrode 102 (FIG. 19(a)). Width of the exposed portions of the AlGaN electron supply layer 113, as viewed in the direction of gate length, after the gate electrode 102 is formed thereon may be adjusted, for example, to 40 nm or larger and 500 nm or smaller, and preferably 300 nm or larger and 500 nm or smaller, respectively on the source electrode 101 side and on the drain electrode 103 side.

Then over the entire top surface of the AlGaN electron supply layer 113 having the gate electrode 102 formed thereon, the SiO₂ film 122 is formed so as to fill up the recess 125, typically by normal-pressure CVD process or the like (FIG. 19(b)).

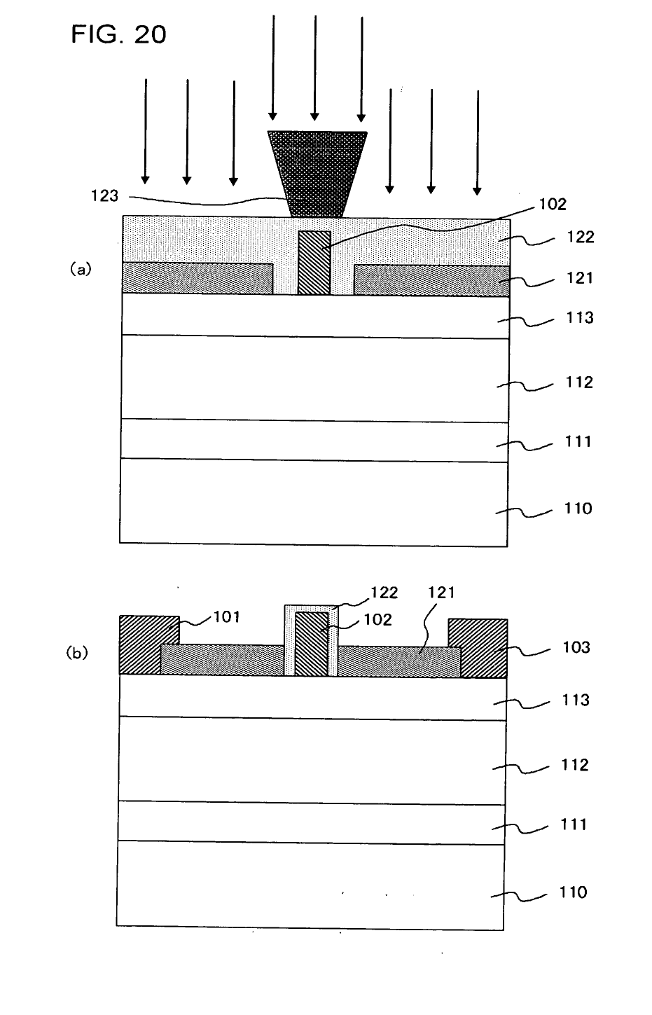

Next, a resist film 123 covering a predetermined region of the top surface of the SiO₂ film 122, more specifically a region above the recess 125, is formed (FIG. 20(a)). The resist film 123 may have a tapered form as being diverted in the direction away from the element forming surface of the substrate 110. The SiO₂ film 122 formed over the SiN film 121 is then selectively etched off through the resist film 123, used as a mask. A predetermined region of the SiN film 121 is further etched off through another mask, to thereby allow the AlGaN electron supply layer 113 to expose. Thereafter, a metal such as Ti/Al is deposited over the AlGaN electron supply layer 113 to thereby form the source electrode 101 and the drain electrode 103, and the product was annealed at 650° C. so as to establish ohmic contact (FIG. 20(b)). The HJFET shown in FIG. 2 is obtained by these procedures.

Also in this Example, effects similar to those in Example 1 may be obtained.

Also in the HJFET shown in FIG. 2, the SiO₂ film 122 highly effective in suppressing leakage current from the gate is formed at around the gate electrode 102, and the SiN film 121 highly effective in reducing current collapse is formed in the other regions, so that an element excellent both in high voltage resistance in the effect of reducing current collapse may be obtained.

In this Example, the entire surface of the gate electrode 102 is covered with the SiO₂ film 122 which is an insulating film. Because the entire surface of the gate electrode 102 is protected, time-dependent degradation of the gate electrode 102 may be prevented. Therefore an element having a still more excellent reliability may be manufactured.

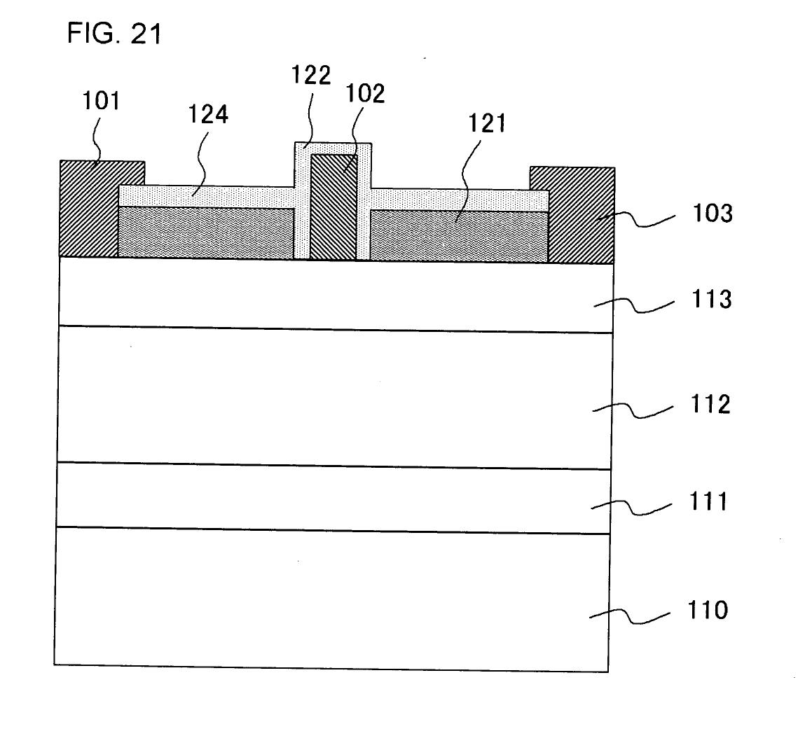

When the SiO₂ film 122 provided over the SiN film 121 is etched off in the process of manufacturing the HJFET shown in FIG. 2 (FIG. 20(a), FIG. 20(b)), the SiO₂ film 122 may be left as being thinned over the SiN film 121. FIG. 21 is a sectional view showing a configuration of thus-configured HJFET.

The basic configuration of the HJFET shown in FIG. 21 is similar to that of the HJFET shown in FIG. 2, except in that the SiO₂ film 124 covers the top portion of the SiN film 121, that the SiO₂ film 124 and the SiO₂ film 122 are formed at the same time in the same process, and that they are made of a continuous and integrated film composed of the same material.

In the configuration shown in FIG. 21, the surface protective film covering the AlGaN electron supply layer 113 in the regions between the SiO₂ film 122 and the source electrode 101 and drain electrode 103 has a double-layered structure of the SiN film 121 and the SiO₂ film 124. As a consequence, mean value of dielectric constant of the surface protective film may be lowered as compared with the case where a single layer of the SiN film 121 having a thickness same as the total thickness of these films is formed.

In addition, by forming the SiO₂ film 122 and the SiO₂ film 124 in a continuous and integrated manner, strength of the SiO₂ film 122 may further be improved even if it is thinned.

The first insulating film (SiO₂ film 122) in this Example is formed over the entire surface of the gate electrode 102, but formation is not limited thereto, wherein it is good enough to cover at least the side faces of the gate electrode 102 with the SiO₂ film 122.

### Third Example

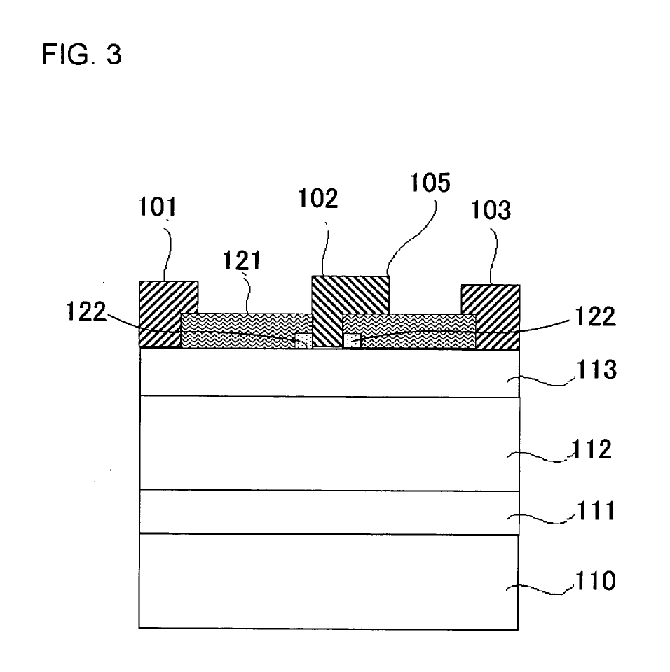

FIG. 3 is a sectional view explaining a configuration of the HJFET of this Example.

In this HJFET, the gate electrode 102 has a field plate portion 105 formed over the SiN film 121, as being stretched out like a pent roof towards the drain electrode 103. The SiO₂ film 122 is provided selectively at around the gate electrode 102, wherein in a sectional view taken along the direction of gate length, the edge on the drain electrode side of the field plate portion 105 is located more closer to the drain electrode 103 side, than the edge on the drain electrode side of the SiO₂ film 122.

In the region on the drain electrode 103 side, the SiN film 121 is provided in contact with the gate electrode 102 and the drain electrode 103, and covers the top surface of the SiO₂ film 122. In the region on the source electrode 101 side, the SiN film 121 is provided in contact with the source electrode 101 and the gate electrode 102, and covers the top surface of the SiO₂ film 122. In this configuration, the bottom surface of the field plate portion 105 does not contact with the top surface of the SiO₂ film 122, and instead the SiN film 121 is disposed therebetween.

The HJFET shown in FIG. 3 is formed over the substrate 110 composed of SiC or the like.

Over the substrate 110, the buffer layer 111 composed of a semiconductor layer is formed. Over the buffer layer 111, the GaN channel layer 112 is formed. Over the GaN channel layer 112, the AlGaN electron supply layer 113 is formed. Over the AlGaN electron supply layer 113, the source electrode 101 and the drain electrode 103 are formed as being brought into ohmic contact therewith, and between them, the gate electrode 102 having the field plate portion 105 is brought into Schottky contact with the AlGaN electron supply layer 113.

Over the surface of the AlGaN electron supply layer 113, the SiO₂ film 122 is provided at around the gate electrode 102. In the region between the gate electrode 102, and the source electrode 101 and drain electrode 103, the SiN film 121 covering the surface of the AlGaN electron supply layer 113 and the upper portion of the SiO₂ film 122 is formed.

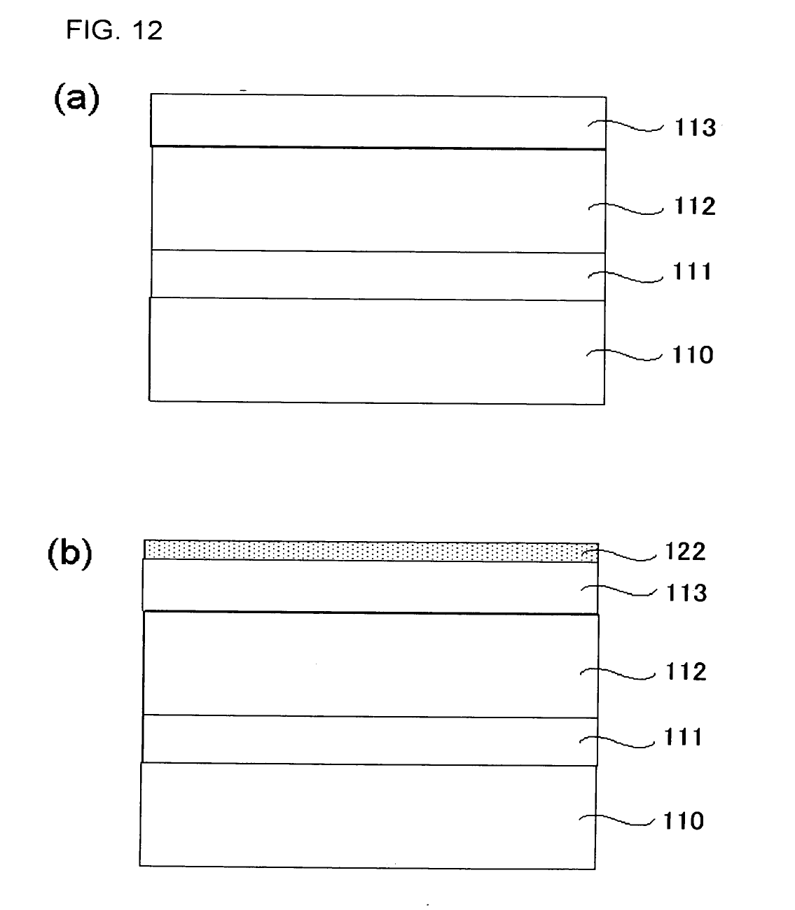

FIG. 12 to FIG. 15 are sectional views showing process steps of manufacturing the HJFET shown in FIG. 3. A method of manufacturing the HJFET shown in FIG. 3 will be explained below, referring to these drawings.

First, over the substrate 110 composed of SiC, semiconductor is grown typically by molecular beam epitaxy (MBE), metal organic vapor phase epitaxy (MOVPE) or the like. In this way, a semiconductor layer structure having, as viewed from the substrate 110 side, the buffer layer 111 (20 nm thick) composed of undoped AlN, the undoped GaN channel layer 112 (2 μm thick), and the AlGaN electron supply layer 113 (25 nm thick) composed of undoped AlGaN stacked therein in this order (FIG. 12(a)) is obtained.

Next, over the AlGaN electron supply layer 113, the SiO₂ film 122 (20 nm thick) is formed typically by normal-pressure CVD (FIG. 12(b)).

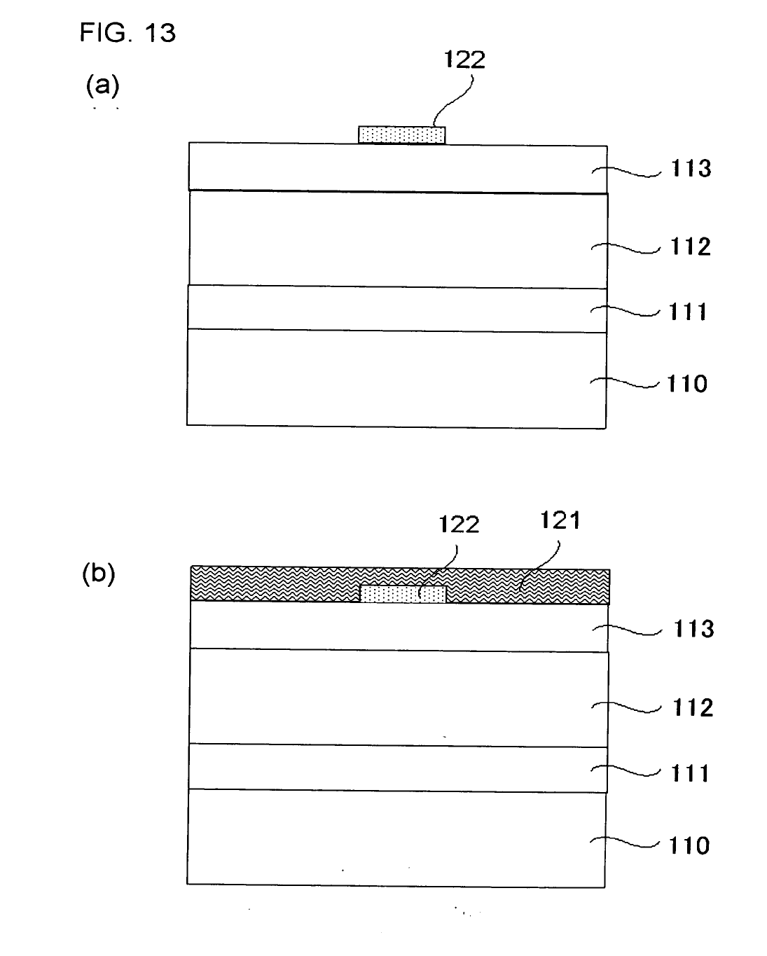

Next, a part of the SiO₂ film 122 and a predetermined region of the epitaxial layer structure are selectively etched off until the GaN channel layer 112 exposes, to thereby form a mesa (not shown) for element isolation. A predetermined region of the SiN film 121 is then selectively removed so as to obtain a predetermined geometry, to thereby expose the AlGaN electron supply layer 113 (FIG. 13(a)).

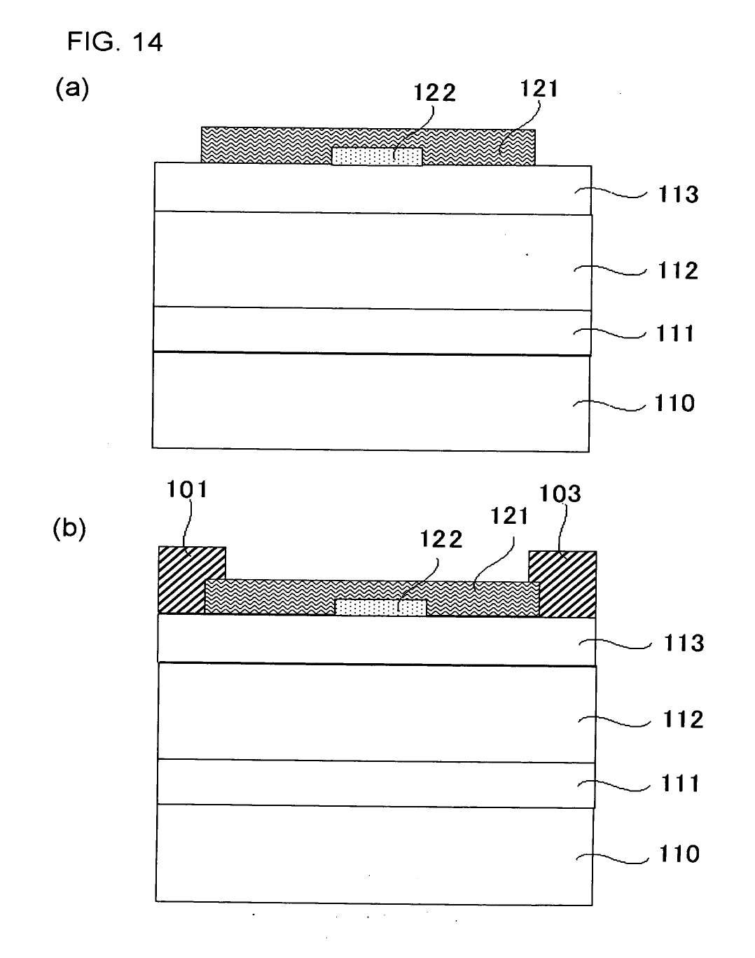

Next, the SiN film 121 (60 nm) is formed typically by plasma CVD, over the AlGaN electron supply layer 113 and the SiO₂ film 122 (FIG. 13(b)). A predetermined region of the SiN film 121 is then etched off through a resist such as photoresist, used as a mask, until the AlGaN electron supply layer 113 exposes (FIG. 14(a)). The SiN film 121 herein is designed so as to cover the SiO₂ film 122, similarly to as described in the First Example.

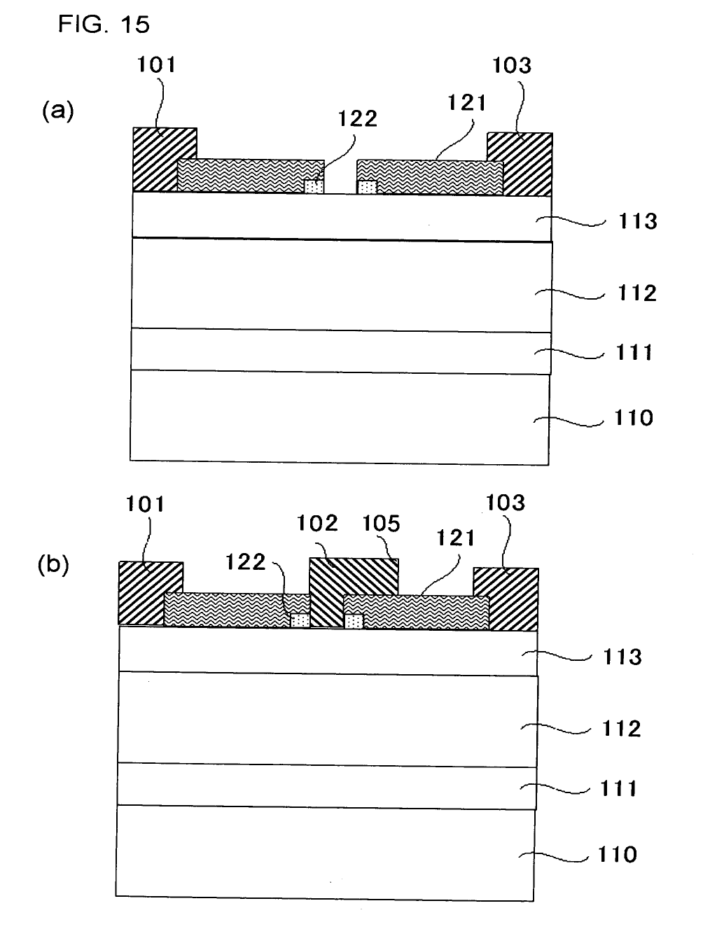

Thereafter, a metal such as Ti/Al is deposited over the AlGaN electron supply layer 11, to thereby form the source electrode 101 and the drain electrode 103, and the product was annealed at 650° C. so as to establish ohmic contact (FIG. 14(b)). A predetermined region of the SiN film 121 and the SiO₂ film 122 are then selectively etched off through photoresist, to thereby form a recess so as to extend through the SiN film 121 and the SiO₂ film 122 (FIG. 15(a)). By this process, similarly to as in First Example, the SiN film 121 and the SiO₂ film 122 expose to the side face of the recess, and the AlGaN electron supply layer 113 exposes to the bottom of the recess.

Over thus-exposed AlGaN electron supply layer 113, a gate metal such as Ni/Au is deposited, to thereby form the gate electrode 102 under Schottky contact. At the same time, the field plate portion 105 composed of Ni/Au is formed as being continuously integrated with the gate electrode 102 (FIG. 15(b)). By these procedures, the HJFET shown in FIG. 3 may be obtained.

In this Example, under a large reverse voltage applied between the gate and the drain, electric field applied to the edge on the drain side of the gate electrode 102 may be moderated by the contribution of the field plate portion 105, and thereby the voltage resistance of the gate may be improved. The field plate portion 105 also shows an effect of suppressing current collapse by increasing response speed of the surface trap under large signal operation, by virtue of its ability of modulating the surface potential.

The configuration of this Example can, therefore, more distinctively express the effect of improving current collapse and voltage resistance of the gate described in the First Example. Such desirable performance may stably be realized, even if the surface conditions may vary due to variation in the manufacturing basis.

In addition, because the SiO₂ film 122 is provided under the field plate portion 105 and selectively at around the side faces of the gate electrode 102, dielectric constant of the insulating films, functioning as a surface protective film, stepwisely varies under the field plate portion 105. This configuration not only reduces leakage current from the gate and current collapse, but also effectively reduces parasitic capacitance induced between the field plate portion 105 and the AlGaN electron supply layer 113 in the region under the field plate portion 105, and thereby suppresses concentration of electric field in the gate electrode 102 on the drain side thereof.

In addition in this Example, the field plate portion 105 may be controllable independently from the gate electrode 102. Because response of the surface trap in this case may be suppressed by fixing the surface potential, current collapse may be suppressed in a still more effective manner, as compared with the case where the surface potential is modulated while adjusting the field plate portion 105 and the gate electrode to the same potential. Such capability of independently controlling the field plate portion 105 shows a large effect, in particular in the Group III nitride semiconductor element in which the surficial negative charge may be of a serious problem.

Fixation of potential of the field plate portion 105 as described in the above may also drastically suppress decrease in the gain, because capacitance of the gate remains almost unchanged even under varied potential of the gate electrode 102.

Length of the field plate portion 105 in the direction of gate length may preferably be adjusted to 0.3 μm or longer, and more preferably 0.5 μm or longer, in view of suppressing current collapse.

From the viewpoint of suppressing lowering in voltage resistance of the gate, the field plate portion 105 may preferably be configured so as not to overlap the drain electrode 103. Because voltage resistance of the gate is determined by a degree of concentration of electric field between the electric field control electrode and the drain electrode, the length of the field plate portion 105 in the direction of gate length is preferably adjusted to not larger than 70% of distance between the gate electrode 102 and the drain electrode 103, from the viewpoint of suppressing lowering in voltage resistance of the gate. The distance between the gate electrode 102 and the drain electrode 103 means distance ranging from the edge on the drain electrode side of the gate electrode 102 to the edge on the gate electrode side of the drain electrode 103, wherein lowering in voltage resistance of the gate may further effectively be suppressed, by adjusting the length of the field plate portion 105 to not longer than 70% of the distance.

In the Patent Document 1 and Patent Document 2 mentioned previously in BACKGROUND ART, there is described configurations having a SiO₂ film provided over the entire region between the field plate portion or the electric field control electrode and the electron supply layer, or additionally over the region on the drain electrode side.

In contrast in this Example, wherein in a sectional view taken along the direction of gate length, the edge on the drain electrode side of the field plate portion 105 is located more closer to the drain electrode 103 side, than the edge on the drain electrode side of the SiO₂ film 122, and the SiO₂ film 122 is selectively provided at around both side faces of the gate electrode 102. Such configuration may raise an effect of more effectively suppressing current collapse and leakage current from the gate, and may reduce parasitic capacitance between the side faces of the gate electrode 102 and the AlGaN electron supply layer 113, both on the source electrode 101 side and the drain electrode 103 side.

The explanation in the above dealt with the case where the field plate portion 105 is composed of the same component with the gate electrode 102, and functions as an electric field control portion, wherein it is not always necessary that the electric field control portion and the gate electrode 102 are configured as being continuously integrated, allowing another configuration having an electric field control electrode independently from the gate electrode 102, over the AlGaN electron supply layer 113 in the region between the gate electrode 102 and the drain electrode 103.

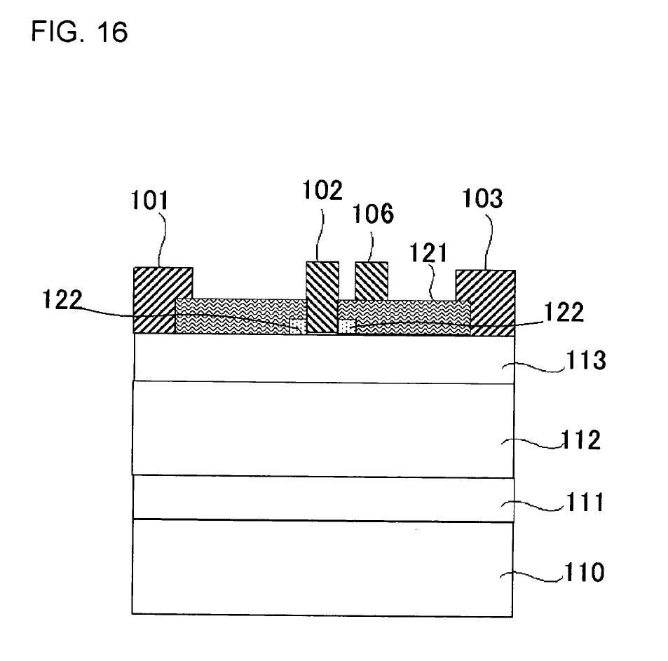

FIG. 16 is a sectional view showing a configuration of such HJFET. In FIG. 16, in place of the gate electrode 102 having the field plate portion 105, the HJFET has the gate electrode 102, and an electric field control electrode 106 provided as being spaced from the gate electrode 102. The SiO₂ film 122 is provided selectively at around the gate electrode 102, wherein the edge on the drain electrode side of the electric field control electrode 106 is located closer to the drain electrode 103 side, than the edge on the drain electrode side of the SiO₂ film 122. In the region on the drain electrode 103 side, the SiN film 121 is provided in contact with the gate electrode 102 and the drain electrode 103, and covers the top surface of the SiO₂ film 122. In the region on the source electrode 101 side, the SiN film 121 is provided in contact with the source electrode 101 and the gate electrode 102, and covers the top surface of the SiO₂ film 122.

In FIG. 16, the electric field control electrode 106 may be controlled independently from the gate electrode 102, and thereby the electric field control electrode 106 and the gate electrode 102 may be applied with potential of different levels. By virtue of this configuration, the field effect transistor may be operated at optimum conditions. Because response of the surface trap may be suppressed by fixing the surface potential, current collapse may be suppressed in a still more effective manner, as compared with the case where the surface potential is modulated while adjusting the electric field control electrode 106 and the gate electrode to the same potential. Such capability of independently controlling the electric field control electrode 106 shows a large effect, in particular in the Group III nitride semiconductor element in which the surficial negative charge may be of a serious problem.

Fixation of potential of the electric field control electrode 106 as described in the above may also drastically suppress decrease in the gain, because capacitance of the gate remains almost unchanged even under varied potential of the gate electrode 102.

The HJFET shown in FIG. 16 may be manufactured using a method of manufacturing the HJFET shown in FIG. 3. Although the case exemplified in the above was such as forming the gate electrode 102 and the field plate portion 105 at the same time, it is also allowable to form the gate electrode 102 and the electric field control electrode 106 in separate process steps. More specifically, process steps of forming the resist having an opening provided therein, and forming each of the electrodes in the opening may be carried out in a separate manner. In this case, the gate electrode 102 and the electric field control electrode 106 may be formed while ensuring a narrower gap therebetween.

### Fourth Example

The individual Examples described in the above may adopt so-called, recessed-gate structure in which the lower portion of the gate electrode is partially embedded into the AlGaN electron supply layer.

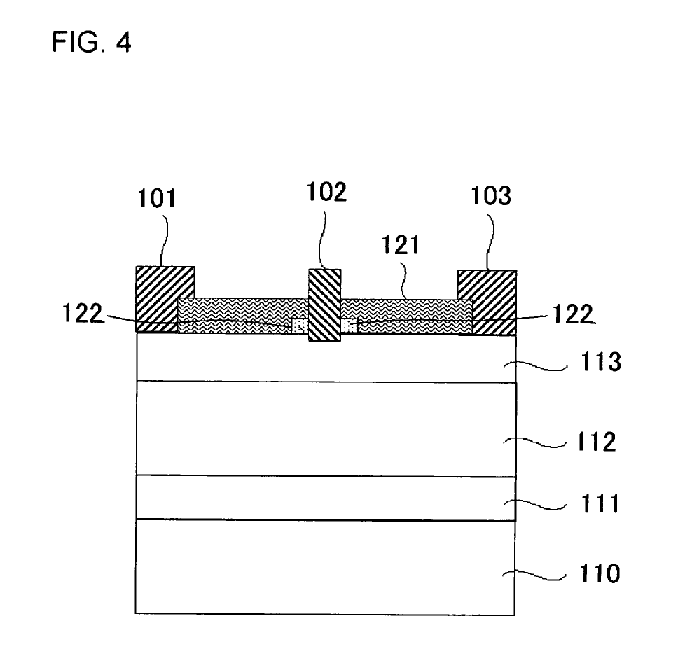

FIG. 4 is a drawing showing a configuration of the HJFET of this Example. FIG. 4 shows an exemplary HJFET adopting the recessed-gate structure. The case where the configuration is shown in the First Example will be explained below.

In the HJFET shown in FIG. 4, the AlGaN electron supply layer 113 is provided between the GaN channel layer 112, and the source electrode 101 and the drain electrode 103, and a recess is provided in the GaN electron supply layer 113 in the region between the source electrode 101 and the drain electrode 103. A part of the lower portion of the gate electrode 102 is embedded into the AlGaN electron supply layer 113, and the source electrode 101 and the drain electrode 103 are provided in contact with the upper surface of the AlGaN electron supply layer 113. Adoption of the recessed-gate structure may further improve voltage resistance of the gate.

The HJFET shown in FIG. 4 may be obtained by etching the AlGaN electron supply layer 113 to form a recess, before the metal destined for the gate electrode 102 is deposited, and then by forming the gate electrode 102.

Alternatively, the individual Examples described in the above may adopt so-called wide recess structure. This will be explained below, referring to the case of the First Example.

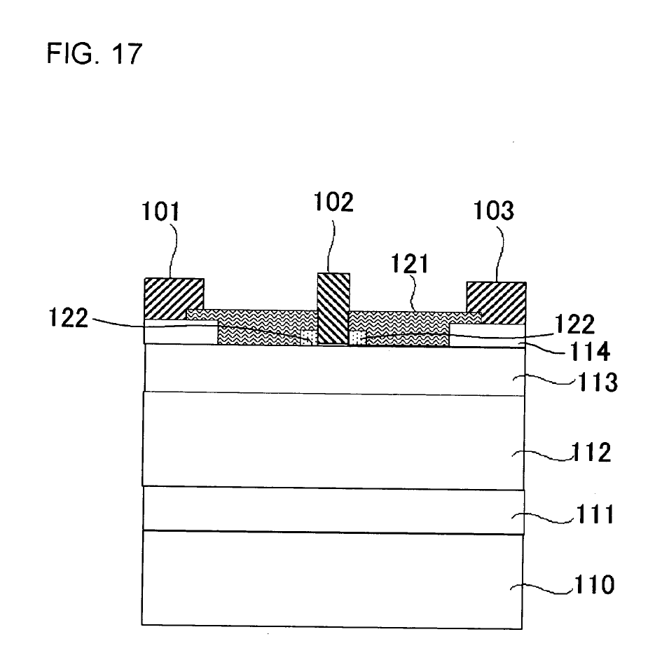

FIG. 17 shows a sectional structure of the HJFET of this Example.

In this HJFET, a contact layer 114 is provided respectively between the source electrode 101 and the AlGaN electron supply layer 113, and between the drain electrode 103 and the AlGaN electron supply layer 113. The contact layer 114 is composed of a undoped AlGaN layer.

The HJFET is formed on the substrate 110 typically composed of SiC. Over the substrate 110, the buffer layer 111 composed of a semiconductor layer is formed. Over the buffer layer 111, the GaN channel layer 112 is formed. Over the GaN channel layer 112, the AlGaN electron supply layer 113 is formed.

Over the AlGaN electron supply layer 113, the source electrode 101 and the drain electrode 103 are formed as being brought into ohmic contact therewith. The gate electrode 102 is provided between the source electrode 101 and the drain electrode 103, wherein the gate electrode 102 and the AlGaN electron supply layer 113 are brought into Schottky contact with each other.

Over the surface of the AlGaN electron supply layer 113, the SiO₂ film 122 is provided in contact with both side faces of the gate electrode 102. The SiN film 121 is provided so as to cover the surface of the AlGaN electron supply layer 113 and the SiO₂ film 122, as being extended from the gate electrode 102 to the source electrode 101 and to the drain electrode 103.

In the HJFET shown in FIG. 17, the contact layer 114 composed of a undoped AlGaN layer is disposed between the source electrode 101 and the AlGaN electron supply layer 113, and between the drain electrode 103 and the AlGaN electron supply layer 113. The contact layer 114 is provided over the AlGaN electron supply layer 113, in the region having the source electrode 101 and the drain electrode 103 formed therein. The contact layer 114 has an opening, and the bottom of the opening is composed of the surface of the AlGaN electron supply layer 113. The bottom surface of the opening is given as a recessed surface, with respect to the top surface of the contact layer 114. The source electrode 101 and the drain electrode 103 are provided in contact with the top surface of the contact layer 114. The gate electrode 102 is provided in contact with the AlGaN electron supply layer 113. The bottom surfaces of the source electrode 101 and the drain electrode 103 are located further above the bottom surface of the gate electrode 102 (on the side more apart from the substrate 110).

The HJFET shown in FIG. 17 is configured as adding the contact layer 114 to the HJFET of the First Example (FIG. 1). According to this configuration, contact resistance may further be reduced, in addition to the effect obtained in the First Example.

Adoption of the wide recess structure alters distribution of electric field at the edge on the drain electrode side of the gate electrode 102, and thereby a more excellent effect of moderating electric field may be obtained.

The HJFET shown in FIG. 17 may be configured also as additionally having the field plate portion 105 or the electric field control electrode 106, and as having the field plate portion 105 or the electric field control electrode 106 extended up above the contact layer 114. In other words, in this Example, in the region between the gate electrode 102 and the drain electrode 103, the field plate portion 105 or the electric field control electrode 106 is formed over the AlGaN electron supply layer 113, while placing the SiN film 121 and the SiO₂ film 122 in between, and the field plate portion 105 or the electric field control electrode 106 may be extended up above the contact layer 114. Moreover, the field plate portion 105 or the electric field control electrode 106 may be controllable independently from the gate electrode 102.

The present invention has been explained referring to the Examples. These Examples are merely exemplary ones, and those skilled in the art will readily understand that there are various modified examples in combinations of the individual constituents and processing, and that such modified examples are also in the scope of the present invention.

For example, the Examples in the above explained the cases where SiC was used as a material composing the substrate 110, wherein any other species of substrate materials such as sapphire, or other Group III nitride semiconductor substrates such as GaN and AlGaN may be adoptable.

The structure of the semiconductor layers provided under the gate electrode 102 is not limited to that shown in the Examples, allowing various embodiments. For example, another possible configuration is such as providing the AlGaN electron supply layer not only to the upper portion of the GaN channel layer 112, but also to the lower portion thereof.

The Group III nitride semiconductor layer structure may occasionally be provided with an intermediate layer or a cap layer. For example, the Group III nitride semiconductor layer structure may contain a structure having a channel layer composed of InₓGa₁₋ₓN (0≦x≦1), an electron supply layer composed of Al_{y}Ga_{1-y}N (0≦y≦1), and a cap layer composed of GaN, stacked therein in this order. By virtue of this configuration, effective Schottky height may be increased, and thereby further larger voltage resistance of the gate may be realized. It is necessary herein to avoid that both of x and y have a value of zero at the same time in the formulae.

1. A field effect transistor comprising:
a Group III nitride semiconductor layer structure containing a hetero junction;
a source electrode and a drain electrode formed, as being apart from each other, over said Group III nitride semiconductor layer structure;
a gate electrode disposed between said source electrode and said drain electrode;
a first insulating film provided over the surface of said Group III nitride semiconductor layer structure, in contact with both side faces of said gate electrode, and containing oxygen as a constitutive element; and
a second insulating film provided over the surface of said Group III nitride semiconductor layer structure, so as to cover the region between said first insulating film and said source electrode, and the region between said first insulating film and said drain electrode, composed of a material different from that composing said first insulating film, and containing nitrogen as a constitutive element.

2. The field effect transistor as claimed in claim 1,
wherein said first insulating film is a SiO₂ film, and said second insulating film is a SiN film.

3. The field effect transistor as claimed in claim 2,
wherein said first insulating film covers the side faces of said gate electrode.

4. The field effect transistor as claimed in claim 3,
wherein said first insulating film covers the entire surface of gate electrode.

5. The field effect transistor as claimed in claim 1,
wherein said second insulating film covers the top surface of said first insulating film.

6. The field effect transistor as claimed in claim 1,
wherein the region of the surface of said Group III nitride semiconductor layer structure covered with said first insulating film is a region which extends up to 40 nm or more from the edge portion on the drain electrode side of said gate electrode.

7. The field effect transistor as claimed in claim 1,
wherein the region of the surface of said Group III nitride semiconductor layer structure covered with said first insulating film is a region which extends up to 500 nm or less from the edge portion on the drain electrode side of said gate electrode.

8. The field effect transistor as claimed in claim 1,
wherein said Group III nitride semiconductor layer structure contains a channel layer composed of InₓGa₁₋ₓN (0≦y≦1) and an electron supply layer composed of Al_{y}Ga_{1-y}N (0≦y≦1).

9. The field effect transistor as claimed in claim 1,
further comprising a contact layer respectively between said source electrode and the surface of said Group III nitride semiconductor layer structure, and between said drain electrode and the surface of said Group III nitride semiconductor layer structure.

10. The field effect transistor as claimed in claim 9,
wherein said contact layer is composed of an undoped AlGaN layer.

11. The field effect transistor as claimed in claim 1,
wherein said gate electrode has a field plate portion formed, over said second insulating film, as being stretched out like a pent roof towards the drain electrode side, and
in the sectional view taken along the direction of gate length,
the edge portion on the drain electrode side of said field plate portion is located more closer to the drain electrode side, than the edge portion on the drain electrode side of said first insulating film.
